(19) United States
(12) Patent Application Publication
(10) Pub. No.: US 2025/0262969 A1
(43) Pub. Date: Aug. 21, 2025

(54) SYSTEM FOR ESTIMATING POWER CAPABILITY OF A VEHICLE BATTERY

(71) Applicant: FORD GLOBAL TECHNOLOGIES, LLC, Dearborn, MI (US)

(72) Inventors: Yonghua LI, Ann Arbor, MI (US); Yan WANG, Ann Arbor, MI (US); Justin T. HUGHES, Allen Park, MI (US)

(21) Appl. No.: 18/443,989

(22) Filed: Feb. 16, 2024

(51) Int. Cl. B60L 53/62; G01R 31/367; G01R 31/389; H03H 17/02

(52) U.S. Cl. CPC B60L 53/62; G01R 31/367; G01R 31/389; H03H 17/0257

(57) ABSTRACT

A traction battery is charged according to output, indicative of power capability of the traction battery or state of charge of the traction battery, from a filter that uses battery equivalent circuit model parameters that depend on a gain factor selected according to a learned capacity and an ohmic resistance of the traction battery.

### TECHNICAL FIELD

The present disclosure relates to a vehicle system for estimating a power capability of a vehicle battery and operating the vehicle according to the power capability.

### BACKGROUND

Electric vehicles (EVs) rely on one or more traction batteries to supply electric energy to a motor for propulsion. The driving operations of the vehicles may depend on the power capability of the traction battery. The power capability may be affected by various factors such as battery temperature, voltage, state of charge (SOC), battery age, or the like.

### SUMMARY

A vehicle includes a traction battery and a controller that charges the traction battery according to output, indicative of power capability of the traction battery or state of charge of the traction battery, from a filter that uses battery equivalent circuit model parameters that depend on a gain factor selected according to a learned capacity and an ohmic resistance of the traction battery such that, for a same temperature and beginning state of charge of the traction battery, a time to achieve a state of charge target value changes as the traction battery ages.

A method includes charging a traction battery according to output, indicative of power capability of the traction battery or state of charge of the traction battery, from a filter that uses battery equivalent circuit model parameters that depend on a gain factor selected according to a learned capacity and an ohmic resistance of the traction battery.

An automotive power system includes a controller that charges a traction battery according to output, indicative of power capability of the traction battery or state of charge of the traction battery such that, for a same temperature and beginning state of charge of the traction battery, a time to achieve a state of charge target value changes as the traction battery ages.

### BRIEF DESCRIPTION OF THE DRAWINGS

FIG. 1 illustrates an example block topology of an electrified vehicle illustrating drivetrain and energy storage components.

FIG. 2 illustrates a block diagram of an arrangement for a traction battery controller of a battery electric vehicle (BEV) to monitor a traction battery of the BEV.

FIG. 3 illustrates a schematic diagram of a conventional equivalent circuit model (ECM) of the traction battery.

FIG. 4 illustrates a flow diagram for a process for calibrating the extended Kalman filter (EKF) filter gain and operating the vehicle accordingly.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The present disclosure, among other things, proposes a system and method for estimating a battery power capability by considering the battery state of health (SOH) as a factor, and operating the vehicle based on the power capability.

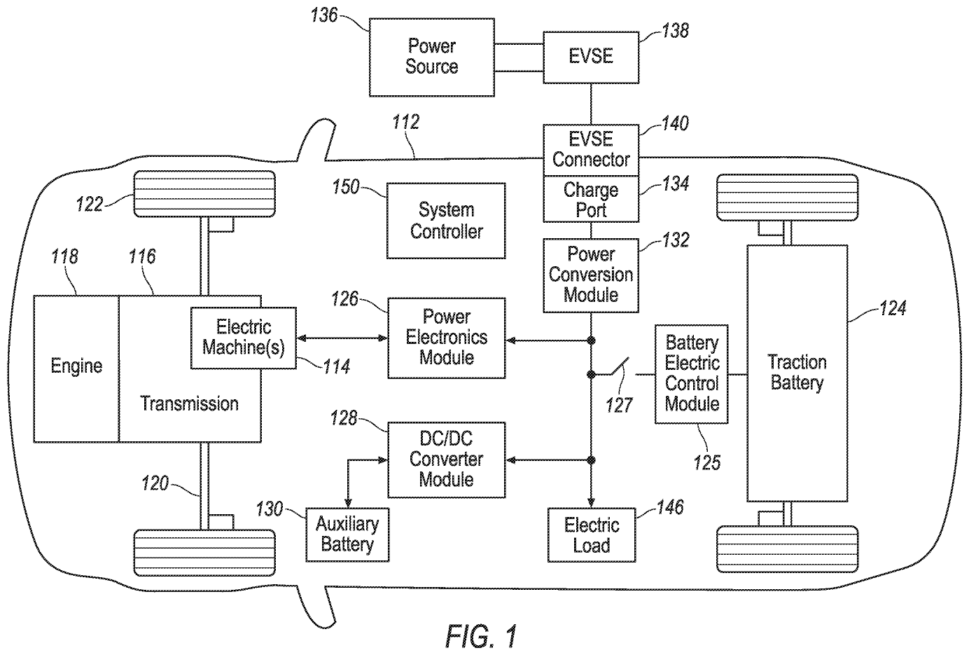

FIG. 1 illustrates a plug-in hybrid-electric vehicle (PHEV). A plug-in hybrid-electric vehicle 112 may comprise one or more electric machines (electric motors) 114 mechanically coupled to a hybrid transmission 116. The electric machines 114 may be capable of operating as a motor or a generator. In addition, the hybrid transmission 116 is mechanically coupled to an engine 118. The hybrid transmission 116 is also mechanically coupled to a drive shaft 120 that is mechanically coupled to wheels 122. The electric machines 114 may provide propulsion and slowing capability when the engine 118 is turned on or off. The electric machines 114 may also act as generators and may provide fuel economy benefits by recovering energy that would be lost as heat in the friction braking system. The electric machines 114 may also reduce vehicle emissions by allowing the engine 118 to operate at more efficient speeds and allowing the hybrid-electric vehicle 112 to be operated in electric mode with the engine 118 off under certain conditions.

A traction battery or battery pack 124 stores energy that may be used by the electric machines 114. The vehicle battery pack 124 may provide a high voltage DC output. The traction battery 124 may be electrically coupled to one or more battery electric control modules (BECM) 125. The BECM 125 may be provided with one or more processors and software applications configured to monitor and control various operations of the traction battery 124. The traction battery 124 may be further electrically coupled to one or more power electronics modules 126. The power electronics module 126 may also be referred to as a power inverter. One or more contactors 127 may isolate the traction battery 124 and the BECM 125 from other components when opened and couple the traction battery 124 and the BECM 125 to other components when closed. The power electronics module 126 may also be electrically coupled to the electric machines 114 and provide the ability to bi-directionally transfer energy between the traction battery 124 and the electric machines 114. For example, a traction battery 124 may provide a DC voltage while the electric machines 114 may operate using a three-phase AC current. The power electronics module 126 may convert the DC voltage to a three-phase AC current for use by the electric machines 114. In a regenerative mode, the power electronics module 126 may convert the three-phase AC current from the electric machines 114 acting as generators to the DC voltage compatible with the traction battery 124. The description herein is equally applicable to a pure electric vehicle. For a pure electric vehicle, the hybrid transmission 116 may be a gear box connected to the electric machine 114 and the engine 118 may not be present.

In addition to providing energy for propulsion, the traction battery 124 may provide energy for other vehicle electrical systems. A vehicle may include a DC/DC converter module 128 that converts the high voltage DC output of the traction battery 124 to a low voltage DC supply that is compatible with other low-voltage vehicle loads. An output of the DC/DC converter module 128 may be electrically coupled to an auxiliary battery 130 (e.g., 12V battery).

The vehicle 112 may be a battery electric vehicle (BEV) or a plug-in hybrid electric vehicle (PHEV) in which the traction battery 124 may be recharged by an external power source 136. The external power source 136 may be a connection to an electrical outlet. The external power source 136 may be an electrical power distribution network or grid as provided by an electric utility company. The external power source 136 may be electrically coupled to electric vehicle supply equipment (EVSE) 138. The EVSE 138 may provide circuitry and controls to and manage the transfer of energy between the power source 136 and the vehicle 112. The external power source 136 may provide DC or AC electric power to the EVSE 138. The EVSE 138 may have a charge connector 140 for plugging into a charge port 134 of the vehicle 112. The charge port 134 may be any type of port configured to transfer power from the EVSE 138 to the vehicle 112. The charge port 134 may be electrically coupled to a charger or on-board power conversion module 132. The power conversion module 132 may condition the power supplied from the EVSE 138 to provide the proper voltage and current levels to the traction battery 124. The power conversion module 132 may interface with the EVSE 138 to coordinate the delivery of power to the vehicle 112. The EVSE connector 140 may have pins that mate with corresponding recesses of the charge port 134. Alternatively, various components described as being electrically coupled may transfer power using a wireless inductive coupling. Although the vehicle 112 is illustrated as a BEV or PHEV with reference to FIG. 1, the present disclosure is not limited thereto. The vehicle 112 may also be a hybrid electric vehicle (HEV) or a fuel cell electric vehicle (FCEV) under essentially the same concept.

One or more electrical loads 146 may be coupled to the high-voltage bus. The electrical loads 146 may have an associated controller that operates and controls the electrical loads 146 when appropriate. Examples of electrical loads 146 may be a heating module, an air-conditioning module, or the like.

The various components discussed may have one or more associated controllers to control and monitor the operation of the components. The controllers may communicate via a serial bus (e.g., Controller Area Network (CAN)) or via discrete conductors. A system controller 150 may be present to coordinate the operation of the various components. It is noted that the system controller 150 is used as a general term and may include one or more controller devices configured to perform various operations in the present disclosure. For instance, the system controller 150 may be programmed to enable a powertrain control function to operate the powertrain of the vehicle 112. The system controller 150 may be further programmed to enable a telecommunication function with various entities (e.g., a server) via a wireless network (e.g., a cellular network).

The system controller 150 and/or the BECM 125, individually or combined, may be programmed to perform various operations regarding the traction battery 124. The traction battery 124 may be a rechargeable battery made of one or more rechargeable cells (e.g., lithium-ion cells). For instance, the BECM 125 may be a traction battery controller operable for managing the charging and discharging of the traction battery 124 and for monitoring operating characteristics of the traction battery 124. The BECM 125 may be operable to implement algorithms to measure (e.g., detect or estimate) the operating characteristics of the traction battery 124. The BECM 125 may control the operation and performance of the traction battery 124 based on the operating characteristics. The operation and performance of other systems and components of the vehicle 112 may be controlled based on the operating characteristics of the traction battery 124.

Operating characteristics of the traction battery 124 may include various parameters. For instance, the operating characteristics may include the charge capacity and the state-of-charge (SOC) of the traction battery 124. The charge capacity of the traction battery 124 is indicative of the maximum amount of electrical energy that the traction battery may store. The charge capacity may reduce over time as the traction battery 124 ages. The charge capacity reduction may be affected by various factors such as the age and/or SOH of the traction battery 124, the number of charging cycles, usage temperature or the like. The SOC of the traction battery 124 is indicative of a present amount of electrical charge stored in the traction battery. The SOC of the traction battery 124 may be represented as a percentage of the maximum amount of electrical charge that may be stored in the traction battery 124. The operating characteristics may further include an internal resistance of the traction battery 124. Like the charge capacity, the internal resistance may vary as the battery ages. In general, the internal resistance increases as the battery becomes older.

Another operating characteristic of the traction battery 124 is the power capability of the traction battery. The power capability of the traction battery 124 is a measure of the maximum amount of power the traction battery can provide (i.e., discharge) or receive (i.e., charge) for a specified time period. As such, the power capability of the traction battery 124 corresponds to discharge and charge power limits which define the amount of electrical power that may be supplied from or received by the traction battery 124 at a given time. These limits can be provided to other vehicle controls, for example, through the system controller 150, so that the information can be used by systems that may draw power from or provide power to the traction battery 124. Vehicle controls need to know how much power the traction battery 124 can provide (discharge) or receive (charge) in order to meet the driver's driving demand and HVAC (Heating, Ventilation and Air Conditioning) demand and to optimize the energy usage. As such, knowing the power capability of the traction battery 124 allows electrical loads and sources to be managed such that the power requested is within the allowed voltage and current limits that the traction battery can handle.

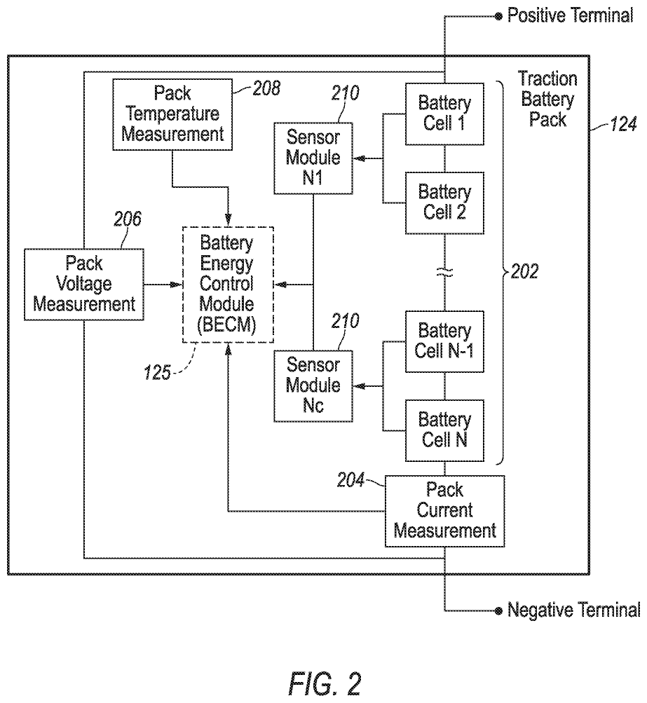

Referring to FIG. 2, with continuing reference to FIG. 1, a block diagram of an arrangement for the BECM 125 to monitor the traction battery 124 is illustrated. In the present example, the BECM 125 may be integrated with the traction battery 124 although the present disclosure is not limited thereto. The traction battery 124 includes a plurality of battery cells 202. The battery cells 202 may be physically connected together (e.g., connected in series as illustrated in FIG. 2).

The BECM 125 may be operable to monitor pack level characteristics of the traction battery 124 such as battery current 204, battery pack voltage 206, and battery temperature 208. The battery current 204 is the current output (i.e., discharged) from or input (i.e., charged) to the traction battery 124. The battery pack voltage 206 is the terminal voltage of the traction battery 124.

The BECM 125 may also be operable to measure and monitor battery cell level characteristics of battery cells 202 of the traction battery 124. For example, terminal voltage, current, and temperature of one or more of battery cells 202 may be measured. The BECM 125 may use one or more battery sensors 210 to measure the battery cell level characteristics. The battery sensors 210 may measure the characteristics of one or multiple battery cells 202. The BECM 125 may utilize an Nc number of battery sensors 210 to measure the characteristics of all battery cells 202. Each battery sensor 210 may transfer the measurements to the BECM 125 for further processing and coordination. In one embodiment, the battery sensors 210 functionality may be incorporated internally to the BECM 125.

The traction battery 124 may have one or more temperature sensors such as thermistors in communication with the BECM 125 to provide data indicative of the temperature of battery cells 202 of the traction battery 124 for the BECM 125 to monitor the temperature of the traction battery and/or the battery cells. The vehicle 112 may further include one or more temperature sensors 208 to provide data indicative of ambient temperature for the BECM 125 to monitor the ambient temperature.

The BECM 125 may control the operation and performance of the traction battery 124 based on the monitored traction battery and battery cell level characteristics. For instance, the BECM 125 may use the monitored characteristics to measure (e.g., detect or estimate) operating characteristics of the traction battery 124 (e.g., the power capability, the SOC, the internal resistance and the like) such as for use in controlling the traction battery and/or vehicle 112.

As known by those of ordinary skill in the art, the BECM 125 may estimate values of parameters of an equivalent circuit model (ECM) (e.g., resistances and capacitances of circuit elements of the ECM) and values of states of the ECM (e.g., voltages and currents across circuit elements of the ECM) through recursive estimation based on such measurements. For instance, the BECM 125 may use some adaptive estimation method, such as extended Kalman filter (EKF), to estimate the values of the model parameters and model states.

For the values of the operating characteristics of the traction battery 124 measured by the BECM 125 to be accurate with the actual values of the operating characteristics of the traction battery, the ECM must accurately model the traction battery 124. For the ECM to accurately model the traction battery 124, (i) the ECM must have an adequate set of parameters (e.g., resistances and capacitances of circuit elements of the ECM) and (ii) the estimated values of the model parameters and model states must be at least substantially similar to the values of the parameters and the states of an ECM that accurately model the traction battery 124 (i.e., the estimated parameter and state values have to be at least substantially similar to the actual parameter and state values).

As set forth, an accurate model of the traction battery 124 enables the BECM 125 to properly control the traction battery 124 which directly affects vehicle performance and driving range for a given full charge. ECMs are widely used in electrified vehicle traction battery control systems to satisfy real time control system requirements for calculation speed and RAM/ROM usage. Particularly, an n-RC ECM where n=1 or 2 is widely used (an n-RC ECM is a type of ECM having “n” RC circuit elements each including a resistor (“R”) parameter and a capacitor (“C”) parameter; with n=1, a 1-RC ECM includes one such RC circuit element; and with n=2, a 2-RC ECM includes two such RC circuit elements). As indicated, the parameters for the ECM are learned with an online learning method such as Kalman Filter or extended Kalman filter (EKF).

In accordance with the present disclosure, the BECM 125 employs an equivalent circuit model of the traction battery 124 that efficiently represents complex battery dynamics of the traction battery 124. The number of parameters of the proposed ECM are less than the number of parameters of multi-RC pair ECMs having three or more RC circuit elements, and the parameters of the proposed ECM can be learned using EKF or similar methods under reasonable BECM capabilities such as CPU utilization ratio and RAM/ROM availability.

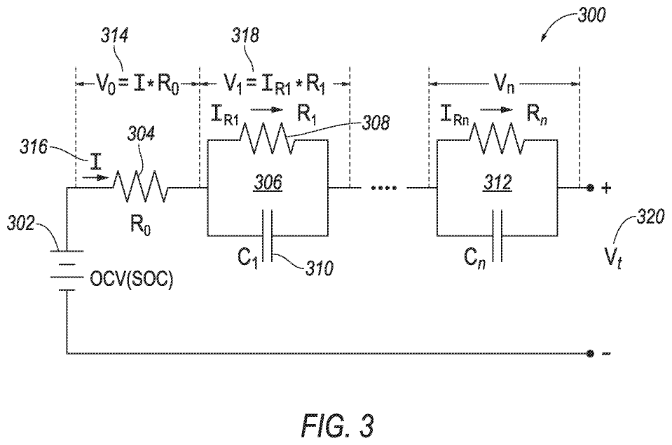

Referring now to FIG. 3, with continuing reference to FIGS. 1 and 2, a schematic diagram of an ECM 300 of the traction battery 124 is shown. Per the ECM 300, the traction battery 124 is modeled as a circuit having in series a voltage source (OCV/(SOC)) 302, a resistor R₀ 304, a first RC pair 306 having a first resistor R₁ 308 and a first capacitor C₁ 310 connected in parallel, and one or more such additional RC pairs 312. As such, the conventional ECM 300 is an n-RC ECM where n≥2.

The voltage source 302 represents the open-circuit voltage (OCV) of the traction battery 124. The OCV of the traction battery 124 depends on the state-of-charge (SOC) and the temperature of the traction battery 124. The resistor R₀ 304 represents an internal resistance of the traction battery 124. The RC pairs represent the diffusion process of the traction battery 124. As such, the diffusion process of the traction battery 124 in the conventional ECM 300 may be described with RC pairs R₁ and C₁, . . . , Rₙ and Cₙ.

Voltage V₀ 314 is the voltage drop across the resistor R₀ 304 due to battery current I 316 which flows across the resistor R₀ 304. Voltage V₁ 318 is the voltage drop across the first RC pair 306 due to battery current IR₁ which flows across the resistor R₁ 308. A voltage drop is across each additional RC pair 312. Voltage Vₜ 320 is the voltage across the terminals of the traction battery 124 (i.e., the terminal voltage).

Parameters of the ECM 300 may include the resistors (i.e., resistor R₀, resistor R₁, and resistor Rₙ) and the capacitors (i.e., capacitor C₁ and capacitor Cₙ). The parameters are to have values whereby the calculated output of the ECM 300 in response to a hypothetical given input is representative of the actual output of the traction battery 124 in response to the actual given input. The values of the parameters can be learned online or locally by the BECM 125 such as with an EKF.

Although some of the variables of the ECM 300 such as the battery current I 316 and the voltage Vₜ 320 may be measured directly in some examples, the determination of other variables may require different means. For example, one way to determine values for at least some of the variables is to apply a recursive parameter estimation method, such as a Kalman filter or an EKF to the equations. A Kalman filter is used for estimating states for a linear system. An EKF may be used for nonlinear systems, by utilizing a linearization process at every time step, to approximate the nonlinear system with a linear time varying system. Since battery parameter estimations are generally non-linear, the EKF may be utilized to more accurately estimate the battery ECM parameters.

In the present example, the 1RC ECM (i.e., n=1) is used to describe the process of the present disclosure for simplicity. It is noted that the although the following description will be made with reference to the 1RC ECM, the present disclosure is not limited thereto. The present disclosure may be applied to any number of RC ECMs under essentially the same concept. (E.g., n=1, 2, 3, 4, etc.)

One way that an EKF can be applied is to consider the current I 316 as the input, the voltage (V₁) as a state, and the term (V_{oc}-Vₜ) as the output. The battery ECM parameters (R₀, R₁ and C₁) or their various combinations are also treated as states to be identified. Once the battery ECM parameters and other unknowns are identified, the power capability can be calculated based on operating limits of a battery voltage and current, and the current battery state.

An EKF is a dynamic system, that is governed by the following equations:

$$\begin{matrix}{X}_{k} = f ( {X}_{k - 1} , {u}_{k - 1} , {w}_{k - 1} ) \\ {Y}_{k} = h ( {X}_{k} , {v}_{k - 1} )\end{matrix} \qquad ( 1 )$$

where: Xₖ includes the state V₂ and the other three battery ECM parameters; uₖ is the input (e.g., battery current); wₖ is the process noise; Yₖ is the output (V_{oc}−Vₜ); and vₖ is the measurement noise.

One such system of equations for the battery model as considered can be shown as follows:

$$X = [ \begin{matrix}{x}_{1} \\ {x}_{2} \\ {x}_{3} \\ {x}_{4}\end{matrix} ] = [ \begin{matrix}{V}_{1} \\ \frac{1}{{R}_{1} {C}_{1}} \\ \frac{1}{{C}_{1}} \\ {R}_{0}\end{matrix} ]$$

The corresponding state space equation, in discrete or continuous time, can be obtained in the form of Equation (1).

Based on the system model shown in Equations (1), an observer is designed to estimate the extended states (x₁, x₂, x₃ and x₄), and correspondingly (V₁, R₀, R₁, and C₁), according to Equations 2-5 as shown below:

$$( {\hat{V}}_{1} ) = {x}_{1} \qquad ( 2 )$$

$$( {\hat{R}}_{0} ) = {x}_{4} \qquad ( 3 )$$

$$( {\hat{R}}_{1} ) = \frac{{x}_{3}}{{x}_{2}} \qquad ( 4 )$$

$$( {\hat{C}}_{1} ) = \frac{1}{{x}_{3}} \qquad ( 5 )$$

The complete set of EKF equations consists of time update equations and measurement update equations. The EKF time update equations project the state and covariance estimate from the previous time step to the current step:

$$\begin{matrix}{\hat{x}}_{k}^{-} = f ( {\hat{x}}_{k - 1} , {u}_{k - 1} , 0 ) \\ {P}_{k}^{-} = {A}_{k} {P}_{k - 1} {A}_{k}^{T} + {W}_{k} {Q}_{k - 1} {W}_{k}^{T}\end{matrix} \qquad ( 6 )$$

where: \hat{x}ₖ⁻ represents an a priori estimate of xₖ; Pₖ⁻ represents an a priori estimate error covariance matrix; Aₖ represents the Jacobian matrix of the partial derivatives of f( ) with respect to X; Pₖ₋₁ represents an a posteriori estimate error matrix of last step; Aₖ represents tje transpose of matrix Aₖ; Wₖ represents the Jacobian matrix of the partial derivatives of f( ) with respect to process noise variable w; Qₖ₋₁ represents a process noise covariance matrix, and Wₖ^{T} represents the transpose of matrix Wₖ.

The measurement update equations correct the state and covariance estimate with the measurement:

$${K}_{k} = {P}_{k}^{-} {{H}_{k}^{T} ( {H}_{k} {P}_{k}^{-} {H}_{k}^{T} + {V}_{k} {R}_{k} {V}_{k}^{T} )}^{- 1} \qquad ( 7 )$$

$${x}_{k} = {\hat{x}}_{k}^{-} + {K}_{k} ( {z}_{k} - h ( {\hat{x}}_{k}^{-} , 0 ) ) \qquad ( 8 )$$

$${P}_{k} = ( I - {K}_{k} {H}_{k} ) {P}_{k}^{-} \qquad ( 9 )$$

where Kₖ represents the EKF gain; Hₖ represents the Jacobian matrix of the partial derivatives of h with respect to X; Hₖ^{T} is the transpose of Hₖ; Rₖ represents a measurement noise covariance matrix; Vₖ represents the Jacobian matrix of the partial derivatives of h with respect to measurement noise variable v; and Vₖ^{T} is the transpose of Vₖ.

From Equation 7, the EKF gain K, is generally inversely proportional to the measurement noise covariance matrix value R. Thus, as the EKF gain factor R increases, EKF gain K decreases, and vice versa.

Generally, in controls theory a large feedback gain normally leads to under damped responses (faster response, and larger oscillations of the controlled variables), and potentially unstable, closed loop system. On the other hand, a small feedback gain normally leads to over damped responses (slower response). Therefore, an improper EKF gain may either lead to large oscillation, or slow learning, of the learned ECM parameters, in particular resistor R₀, and directly affects the quality of power capability estimation, in terms of estimation accuracy (bias) or learning speed.

As discussed above, the parameter of the ECM 300 may be affected by various factors such as the battery temperature and SOC. The present disclosure focuses on the parameters affected by the battery SOH as affected by the battery age and recharge cycles. More specifically, the present disclosure proposes a method for periodically adjusting and/or calibrating the EKF gain K that is used for determining parameters of the ECM 300 by considering the internal resistance and capacity of the traction battery 124 as varied by the battery SOH.

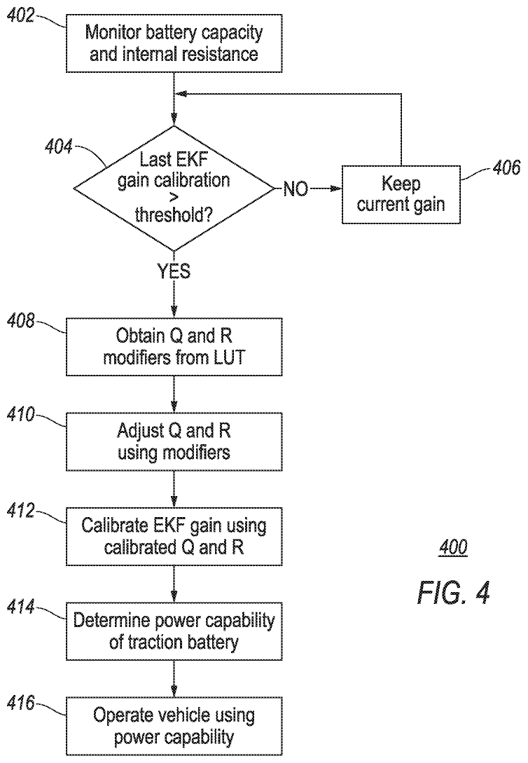

Referring to FIG. 4, an example flow diagram 400 for a process for calibrating the EKF gain of one embodiment of the present disclosure is illustrated. With continuing reference to FIGS. 1 to 3, the process 400 may be independently or collectively implemented via one or more components of the vehicle 112 such as the BECM 125, the system controller 150 or the like. For simplicity, the following description will be made with reference to the BECM 125.

At operation 402, the BECM 125 monitors and records battery operating parameters of the traction battery 124. In the present example, the BECM 125 monitors and records two parameters that are affected by the SOH of the traction battery 124: (i) the capacity of the traction battery 124, and (ii) the internal resistance of the traction battery 124. The total capacity of the traction battery 124 reduces over time as the battery 124 ages. The BECM 125 may continuously monitor the battery capacity and record the most recent capacity in a non-volatile storage device onboard the vehicle 112 (e.g., integrated with the BECM 125). Due to the characteristics of the traction battery 124, the internal resistance may vary depending on various factors such as the battery temperature 208 and the SOC of the traction battery 124. Therefore, the BECM 125 may be configured to monitor the internal resistance at only one or more predefined conditions to provide a more accurate measurement. As a non-limiting example, the BECM 125 may be configured to measure the internal resistance of the traction battery 124 at a predefined SOC of 90% and a predefined battery temperature of 25° C. as these two predefined conditions may be commonly met. Like the capacity parameter, the most recent measured internal resistance may be stored in the non-volatile storage device.

The BECM 125 may be configured to calibrate the EKF gain K in a periodic manner to reduce the processing power. In other words, the BECM 125 does not need to perform the calibration continuously at the first instance when one of the capacity or internal resistance parameters are updated. As a non-limiting example, the EKF gain calibration may be performed at a time interval of at least three months. At operation 404, the BECM 125 verifies if the calibration internal threshold (e.g., three months) has been passed. If the answer is no, the process proceeds to operation 406 to keep the current EKF gain K without calibration.

Otherwise, if the calibration interval threshold has been passed, the process proceeds to operation 408 and the BECM 125 obtains modifiers from a lookup table (LUT) for EKF gain calibration. The vehicle 112 may be provided with the LUT with predetermined values by the vehicle manufacturer. In one example, the LUT may reflect the parameter change caused by the reduction of SOH of the traction battery 124 over time. More specifically, the LUT may be a 3-dimensional (3D) table having an input X-axis indicative of the battery capacity, an input Y-axis indicative of the battery internal resistance, and an output Z-axis indicative of the EKF gain modifiers. Thus, once the most recent battery capacity on the X-axis and internal resistance on the Y-axis have been determined, the BECM 125 may determine the EKF gain modifier value on the Z-axis from the LUT. Alternatively, the LUT may be simplified into a 2D table having an input indicative of a battery life indicator which takes into account both the capacity and internal resistance of the traction battery 124.

In the present example, the process 400 may be configured to modify two parameters of the EKF: (i) the process noise covariance matrix Q utilized in the above equation (6); and (ii) the measurement noise covariance matrix R utilized in the above equation (7) for the EKF gain K calculation. The Z-axis output of the LUT may include one or more of a process noise covariance matrix modifier Q_{g}, and a measurement noise covariance matrix modifier R_{g}. The BECM 125 determines the modifiers Q_{g} and R_{g} using the most recent capacity and internal resistance of the traction battery 124 at operation 408.

With the modifiers Q_{g} and R_{g} determined, at operation 410, the BECM 125 adjusts the process noise covariance matrix Q and the measurement noise covariance matrix R using the following equations:

$${Q}_{life} = Q \cdot {Q}_{g} \qquad ( 10 )$$

$${R}_{life} = R \cdot {R}_{g} \qquad ( 11 )$$

where Q_{life} denotes the life-adjusted process noise covariance matrix Q and R_{life} denotes the life-adjusted process noise covariance matrix.

At operation 412, the BECM calibrates the gain K of the EKF using the life-adjusted process noise covariance matrix Q_{life} and the life-adjusted process noise covariance matrix R_{life} by applying the parameters into equations (6) and (7) to determine updated ECM parameters.

At operation 414, the BECM 125 estimates the power capability of the traction battery 124. With knowledge of the updated ECM parameters, BECM 125 utilizes known equations for estimating the charging and discharging battery power capability, respectively.

At operation 416, the BECM 125 operates the vehicle 112 and/or the traction battery 124 according to the estimated power capability of the traction battery.

The algorithms, methods, or processes disclosed herein can be deliverable to or implemented by a computer, controller, or processing device, which can include any dedicated electronic control unit or programmable electronic control unit. Similarly, the algorithms, methods, or processes can be stored as data and instructions executable by a computer or controller in many forms including, but not limited to, information permanently stored on non-writable storage media such as read only memory devices and information alterably stored on writeable storage media such as compact discs, random access memory devices, or other magnetic and optical media. The algorithms, methods, or processes can also be implemented in software executable objects. Alternatively, the algorithms, methods, or processes can be embodied in whole or in part using suitable hardware components, such as application specific integrated circuits, field-programmable gate arrays, state machines, or other hardware components or devices, or a combination of firmware, hardware, and software components.

While exemplary embodiments are described above, it is not intended that these embodiments describe all possible forms encompassed by the claims. The words used in the specification are words of description rather than limitation, and it is understood that various changes may be made without departing from the spirit and scope of the disclosure. The words processor and processors may be interchanged herein, as may the words controller and controllers.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. A vehicle comprising:
a traction battery; and
a controller configured to charge the traction battery according to output, indicative of power capability of the traction battery or state of charge of the traction battery, from a filter that uses battery equivalent circuit model parameters that depend on a gain factor selected according to a learned capacity and an ohmic resistance of the traction battery such that, for a same temperature and beginning state of charge of the traction battery, a time to achieve a state of charge target value changes as the traction battery ages.

2. The vehicle of claim 1, wherein the filter is an extended Kalman filter.

3. The vehicle of claim 2, wherein the extended Kalman filter has an input based on current of the traction battery.

4. The vehicle of claim 2, wherein the battery equivalent circuit model parameters define a state of the extended Kalman filter.

5. The vehicle of claim 1, wherein the battery equivalent circuit model parameters include internal resistance of the traction battery, charge transfer resistance of the traction battery, or a double layer capacitance of the traction battery.

6. The vehicle of claim 1, wherein the gain factor corresponds to a measurement noise covariance matrix value or a process noise covariance matrix value.

7. The vehicle of claim 1, wherein the controller is further configured to estimate a variable gain based on the gain factor and estimate the battery equivalent circuit model parameters based on the variable gain.

8. The vehicle of claim 7, wherein the gain factor corresponds to a measurement noise covariance matrix value and wherein the variable gain is a multiplication of the gain factor.

9. A method comprising:
charging a traction battery according to output, indicative of power capability of the traction battery or state of charge of the traction battery, from a filter that uses battery equivalent circuit model parameters that depend on a gain factor selected according to a learned capacity and an ohmic resistance of the traction battery.

10. The method of claim 9, wherein the filter is an extended Kalman filter.

11. The method of claim 10, wherein the extended Kalman filter has an input based on current of the traction battery.

12. The method of claim 10, wherein the battery equivalent circuit model parameters define a state of the extended Kalman filter.

13. The method of claim 9, wherein the battery equivalent circuit model parameters include internal resistance of the traction battery, charge transfer resistance of the traction battery, or a double layer capacitance of the traction battery.

14. The method of claim 9, wherein the gain factor corresponds to a measurement noise covariance matrix value or a process noise covariance matrix value.

15. The method of claim 9 further comprising estimating a variable gain based on the gain factor and estimating the battery equivalent circuit model parameters based on the variable gain.

16. The method of claim 15, wherein the gain factor corresponds to a measurement noise covariance matrix value and wherein the variable gain is a multiplication of the gain factor.

17. An automotive power system comprising:
a controller configured to charge a traction battery according to output, indicative of power capability of the traction battery or state of charge of the traction battery, such that for a same temperature and beginning state of charge of the traction battery, a time to achieve a state of charge target value changes as the traction battery ages.

18. The automotive power system of claim 17, wherein the output is from a filter that uses battery equivalent circuit model parameters that depend on a gain factor selected according to a learned capacity and an ohmic resistance of the traction battery.
